(19) United States
(12) Patent Application Publication
(10) Pub. No.: US 2008/0070371 A1
(43) Pub. Date: Mar. 20, 2008

(54) Semiconductor Device and Manufacturing Method Thereof

(75) Inventor: Ting-Sing Wang, Baoshan Township (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: PROMOS TECHNOLOGIES INC., Hsinchu (TW)

(21) Appl. No.: 11/566,761

(22) Filed: Dec. 5, 2006

(30) Foreign Application Priority Data
Sep. 18, 2006 (TW) 95134481

(51) Int. Cl. H01L 21/336

(52) U.S. Cl. 438/301

(57) ABSTRACT

A semiconductor device includes a substrate, a gate electrode, a pair of first impurity regions, a pair of second impurity regions and at least one dummy pattern. The gate electrode is positioned above the substrate. The first impurity regions are positioned in the substrate and near both sides of the gate electrode. The second impurity regions are positioned in the first impurity regions respectively, and the dopant concentration of the first impurity regions is lower than the dopant concentration of the second impurity regions. The dummy pattern is positioned over the first impurity regions and exposes the second impurity regions.

### RELATED APPLICATIONS

The present application is based on, and claims priority from, Taiwan Application Serial Number 95134481, filed Sep. 18, 2006, the disclosure of which is hereby incorporated by reference herein in its entirety.

### BACKGROUND

1. Field of Invention

The present invention relates to active solid-state devices. More particularly, the present invention relates to active solid-state devices with double diffused drains (DDDs).

2. Description of Related Art

Typically, integrated circuits (ICs) operate at various operating voltages. Therefore, transistors in these ICs must withstand certain voltage thresholds. For example, transistors with gate lengths of less than 0.25 um typically must operate at less than 2.5 volts, while transistors with a longer gate length (>0.3 um) may operate at well over 3.0 volts. In certain high voltage applications such as power supplies and hard-disk controllers, even higher operating voltages may be required.

One undesirable effect when applying a high operating voltage to a MOS transistor not designed for such a high voltage is the accumulation of hot electrons at and around the junction of the channel and drain of the transistor. In turn, ionized electrons resulting from the hot electrons move to the drain, thereby causing the drain current to increase. When hot electrons increase to a point where the source/drain junction voltage exceeds a certain level, the source/drain junction of the transistor breaks down, thereby causing damage to the transistor. That certain level of source/drain junction voltage is also known as the breakdown voltage, and must be increased in high voltage environments where a high operating voltage is applied to the transistors.

In order to provide a higher breakdown voltage, a double diffused drain (DDD) is typically provided in many MOS transistors that need to operate in the high voltage environment. DDDs help to suppress the hot electron effect, thereby reducing electrical breakdown of the source/drain under a high operating voltage. However, the method for manufacturing the DDDs is minute and complicated, thereby increasing the manufacturing cost of the transistors.

Moreover, in order to reduce the contact resistance between silicone and metal conductive lines, a silicide layer is typically formed over the gate electrodes and the source/drain electrodes of the transistors. However, in a MOS transistor with DDDs, the silicide layer is only formed over the high doped regions of the DDDS, and the low doped regions of the DDDs do not need silicide formed thereon. For example, an n type doped drain (NDD) of a DDD does not need silicide formed thereon. If the NDD has a silicide layer formed thereon, metal ions would tunnel under the NDD, and influence the efficiency of the transistors.

One solution is forming a protection layer over the NDD before forming the silicide layer to prevent silicide from being formed over the NDD. However, this solution needs at least one photo mask to form the protection layer, thereby increasing the manufacturing cost and reducing the yield rate.

### SUMMARY

According to one embodiment of the present invention, a semiconductor device includes a substrate, a gate electrode, a pair of first impurity regions, a pair of second impurity regions and at least one dummy pattern. The gate electrode is positioned above the substrate. The first impurity regions are positioned in the substrate and near both sides of the gate electrode. The second impurity regions are positioned in the first impurity regions respectively, and the dopant concentration of the first impurity regions is lower than the dopant concentration of the second impurity regions. The dummy pattern is positioned over the first impurity regions and exposes the second impurity regions.

According to another embodiment of the present invention, a method for manufacturing a semiconductor device includes the following steps: Firstly, a substrate is provided. Then, a gate structure and at least one dummy structure are formed on the substrate, wherein the dummy structure is located apart from the gate structure. Next, a first doping process is performed for forming at least two first impurity regions in the substrate, wherein the first impurity regions are positioned near both sides of the gate structure respectively. Then, a pair of spacers is formed adjacent to both sides of the gate structure respectively, and a pair of dummy spacers is formed simultaneously adjacent to both sides of the dummy structure respectively. Finally, a second doping process is performed for forming at least two second impurity regions in the first impurity regions respectively, wherein the dopant concentration of the first impurity regions is lower than the dopant concentration of the second impurity regions.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A and FIG. 1B are a sectional view and a top view of a semiconductor device respectively according to one embodiment of the present invention;

FIG. 2A and FIG. 2B are a sectional view and a top view of a semiconductor device respectively according to another embodiment of the present invention; and

FIGS. 3A-3D are cross-sectional diagrams of a method for manufacturing a semiconductor device according to yet another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

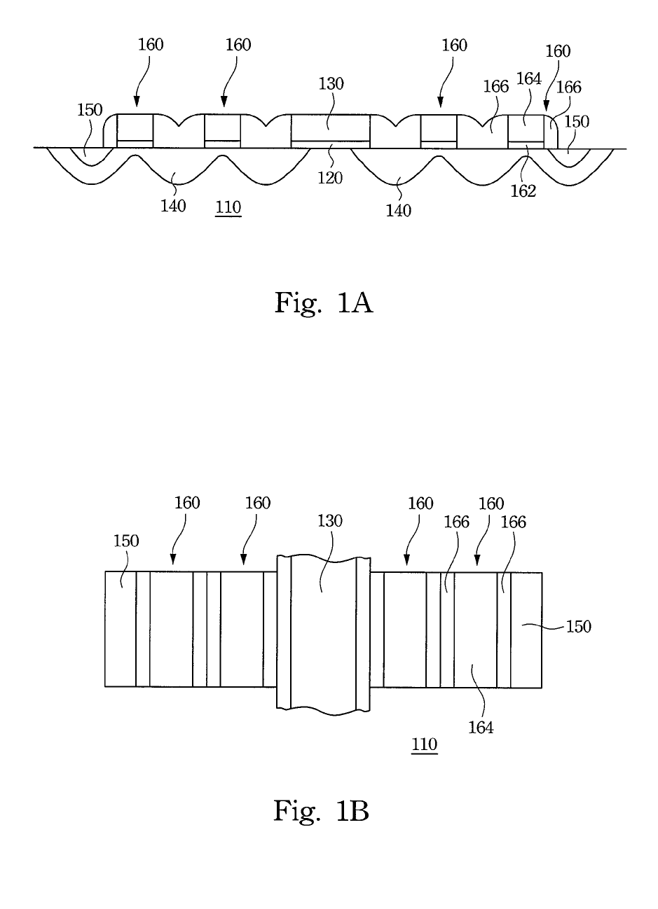

Refer to FIG. 1A and FIG. 1B. FIG. 1A is a sectional view of a semiconductor device according to one embodiment of the present invention. FIG. 1B is a top view of the semiconductor device shown in FIG. 1A. As shown in FIG. 1A and FIG. 1B, a semiconductor device includes a substrate 110, a gate electrode 130, a pair of first impurity regions 140, a pair of second impurity regions 150 and at least one dummy pattern 160. The gate electrode 130 is positioned above the substrate 110. The first impurity regions 140 are positioned in the substrate 110 and near both sides of the gate electrode 130. The second impurity regions 150 are positioned in the first impurity regions 140 respectively, and the dopant concentration of the first impurity regions 140 is lower than the dopant concentration of the second impurity regions 150. The dummy pattern 160 is positioned over the first impurity regions 140 and exposes the second impurity regions 150. Furthermore, a gate dielectric layer 120 may be positioned between the substrate 110 and the gate electrode 130.

More specifically, the dummy pattern 160 may include a dummy dielectric layer 162 and a dummy gate 164. The dummy dielectric layer 162 is positioned over the first impurity regions 140. The dummy gate 164 is positioned on the dummy dielectric layer 162. Particularly, the dummy dielectric layer 162, the dummy gate 164, the gate dielectric layer 120 and the gate electrode 130 may be formed simultaneously without additional photo masks. The dummy pattern may further include a pair of dummy spacers 166. The dummy spacers 166 are located adjacent to both sides of the dummy gate 164 and the dummy dielectric layer 162 respectively. Moreover, the dummy gate may be a floating gate.

As shown in FIG. 1A and FIG. 1B, the number of the dummy patterns 160 may be plural, and the dummy patterns 160 are linked together. That is, the dummy patterns 160 are positioned over the first impurity regions 140 and expose the second impurity regions 150. Therefore, the dummy patterns 160 may be employed as a mask to perform a self-aligned doping process when forming the second impurity regions 150, and no additional photo masks is required. Furthermore, the dummy patterns 160 may also be employed as a mask to perform a self-aligned silicide process when forming silicide over the second impurity regions 150, and no additional photo masks is required as well. In other words, manufacturing the semiconductor device according to this embodiment requires less photo masks than the prior art.

In this embodiment, the length of each of the dummy gate 164 may be about 0.2 μm, and the dummy gates 164 of the dummy patterns 160 may be located about 0.2 μm apart from each other. Furthermore, the second impurity regions 150 may be located about 0.8 μm apart from the gate electrode 130. The disclosed dimensions are only examples, and hence the scope or spirit of the invention should not be limited by them. The detailed dimensions of the semiconductor should depend on actual requirements.

The terms “about” as used herein may be applied to modify any quantitative representation which could permissibly vary without resulting in a change in the basic function to which it is related. For example, a dummy pattern as disclosed herein having a dummy gate with a length about 0.2 μm may permissibly have a somewhat different length of dummy gate within the scope of the invention if its protecting capability is not materially altered.

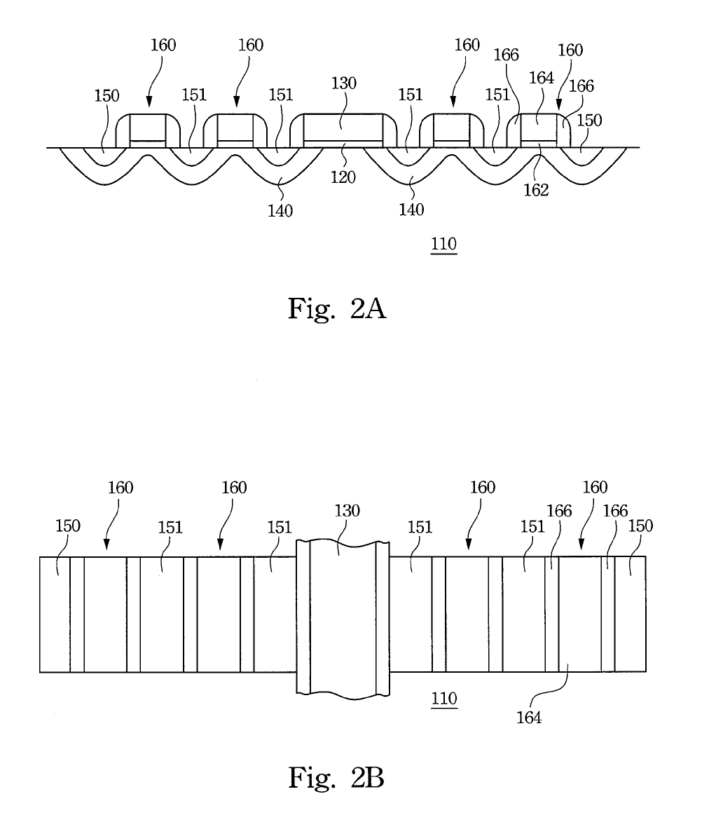

Refer to FIG. 2A and FIG. 2B. FIG. 2A is a sectional view of a semiconductor device according to another embodiment of the present invention. FIG. 2B is a top view of the semiconductor device shown in FIG. 2A. As shown in FIG. 2A and FIG. 2B, the number of the dummy patterns 160 may be plural, and the dummy patterns 160 are separated. If the first impurity regions 140 are extended too long, the series resistance of the first impurity regions 140 will be increased. Therefore, the dummy patterns 160 are separated in this embodiment to prevent the first impurity regions 140 from being extended too long, thereby reducing the series resistance of the first impurity regions 140. Particularly, because the dummy patterns 160 are separated, plural second impurity regions (for example, second impurity regions 151) are formed between the dummy patterns 160. However, only a part of the second impurity regions is electrically connected to drain potential, and the others are floating. For example, in FIG. 2A, the outermost second impurity regions 150 are electrically connected to drain potential, and the other second impurity regions 151, between the dummy patterns 160, are floating.

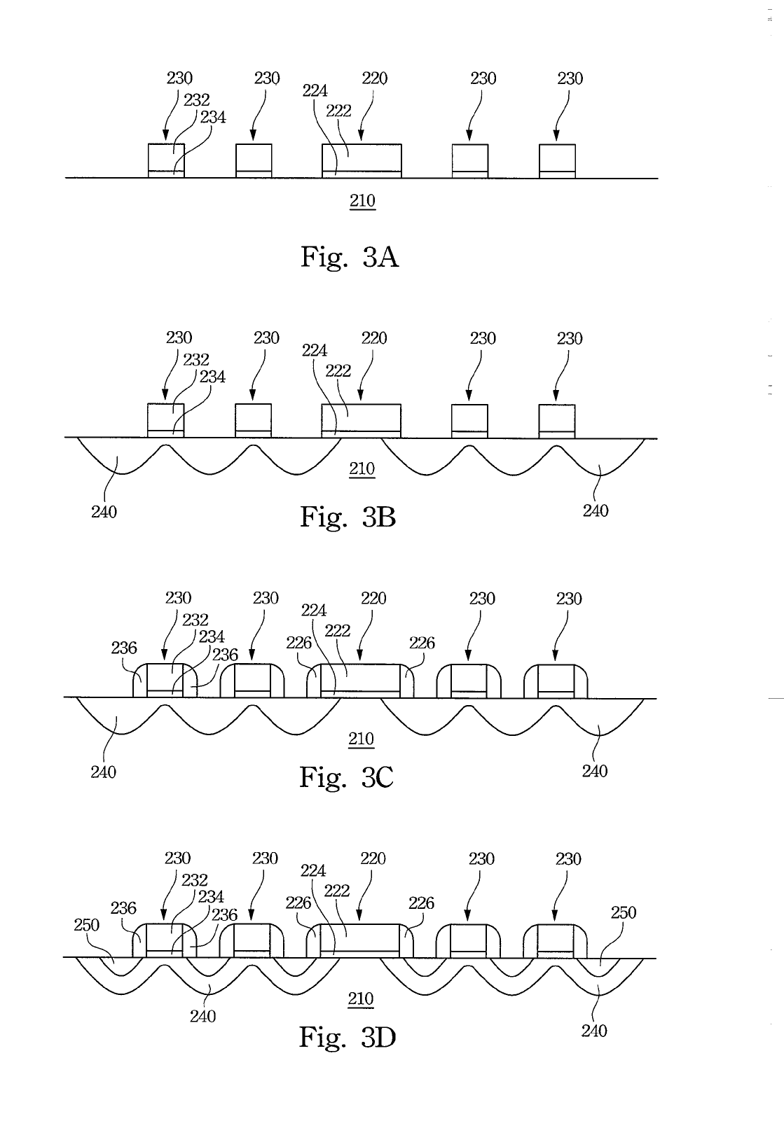

Refer to FIGS. 3A-3D. FIGS. 3A-3D are cross-sectional diagrams of a method for manufacturing a semiconductor device according to yet another embodiment of the present invention.

As shown in FIG. 3A, a gate structure 220 and at least one dummy structure 230 are formed on the substrate 210, wherein the dummy structure 230 is located apart from the gate structure 220. The gate structure 220 may have a gate dielectric layer 224 and a gate electrode 222 positioned on the gate dielectric layer 224. Similarly, the dummy structure 230 may have a dummy dielectric layer 234 and a dummy gate 232 as well. Particularly, the dummy structure 230 and the gate structure 220 may be formed by the same lithography and etching process, and no additional photo masks are required.

As shown in FIG. 3B, a first doping process is then performed to form at least two first impurity regions 240 in the substrate 210, wherein the first impurity regions 240 are positioned near both sides of the gate structure 220 respectively. More specifically, the first doping process is a self-aligned doping process which employs the gate structure 220 and the dummy structure 230 as a mask.

As shown in FIG. 3C, a pair of spacers 226 is formed adjacent to the both sides of the gate structure 220 respectively. Simultaneously, a pair of dummy spacers 236 is formed adjacent to both sides of the dummy structure 230 respectively.

As shown in FIG. 3D, a second doping process is performed to form at least two second impurity regions 250 in the first impurity regions 240 respectively, wherein the dopant concentration of the first impurity regions 240 is lower than the dopant concentration of the second impurity regions 250. More specifically, the second doping process is a self-aligned doping process which employs the gate structure 220, the spacers 226, the dummy structure 230 and the dummy spacers 236 as a mask.

As embodied and broadly described herein, the semiconductor device and the manufacturing method thereof according to the embodiments of the invention have the following advantages:

(1) The dummy pattern according to the mentioned embodiments is positioned over the first impurity regions and exposes the second impurity regions. Therefore, the dummy pattern may be employed as a mask to perform a self-aligned doping process when forming the second impurity regions, and additional photo masks may not be required.

(2) Furthermore, the dummy pattern may also be employed as a mask to perform a self-aligned silicide process when forming silicide over the second impurity regions, and no additional photo masks is required as well.

(3) In conclusion, manufacturing the semiconductor device according to the mentioned embodiments saves at least two photo masks as compared to the prior art.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device comprising:
a substrate;
a gate electrode positioned above the substrate;
at least two first impurity regions positioned in the substrate and near both sides of the gate electrode;
at least two second impurity regions positioned in the first impurity regions respectively, wherein the dopant concentration of the first impurity regions is lower than the dopant concentration of the second impurity regions; and
at least one dummy pattern positioned over the first impurity regions and exposing the second impurity regions.

2. The semiconductor device of claim 1, further comprising:
a gate dielectric layer positioned between the substrate and the gate electrode.

3. The semiconductor device of claim 1, wherein the dummy pattern comprises:
a dummy dielectric layer positioned over the first impurity regions; and
a dummy gate positioned on the dummy dielectric layer.

4. The semiconductor device of claim 3, wherein the dummy gate is a floating gate.

5. The semiconductor device of claim 3, wherein the dummy pattern further comprises:
a pair of dummy spacers adjacent to both sides of the dummy gate and the dummy dielectric layer respectively.

6. The semiconductor device of claim 1, wherein the number of the dummy patterns is plural.

7. The semiconductor device of claim 6, wherein the dummy patterns are linked together.

8. The semiconductor device of claim 7, wherein each of the dummy patterns has a dummy gate, and the length of the dummy gate is about 0.2 μm.

9. The semiconductor device of claim 8, wherein the dummy gates of the dummy patterns are located about 0.2 u m apart from each other.

10. The semiconductor device of claim 7, wherein the second impurity regions are located about 0.8 μm apart from the gate electrode.

11. The semiconductor device of claim 6, wherein the dummy patterns are separated.

12. A method for manufacturing a semiconductor device, comprising the steps of:
providing a substrate;
forming a gate structure and at least one dummy structure on the substrate, wherein the dummy structure is located apart from the gate structure;
performing a first doping process for forming at least two first impurity regions in the substrate, wherein the first impurity regions are positioned near both sides of the gate structure respectively;
forming a pair of spacers adjacent to the both sides of the gate structure respectively and simultaneously forming a pair of dummy spacers adjacent to both sides of the dummy structure respectively; and
performing a second doping process for forming at least two second impurity regions in the first impurity regions respectively, wherein the dopant concentration of the first impurity regions is lower than the dopant concentration of the second impurity regions.

13. The method of claim 12, wherein the first doping process employs the gate structure and the dummy structure as a mask.

14. The method of claim 12, wherein the second doping process employs the gate structure, the spacers, the dummy structure and the dummy spacers as a mask.
